(19) United States
(12) Patent Application Publication
(10) Pub. No.: US 2006/0104129 A1
(43) Pub. Date: May 18, 2006

(54) Method for memory access and corresponding device

(76) Inventors: Michel Chevroulet, Neuchatel (CH); Bart De Geeter, Neuchatel (CH)

Correspondence Address: BLANK ROME LLP, 600 NEW HAMPSHIRE AVENUE, N.W., WASHINGTON, DC, 20037, US

(21) Appl. No.: 11/274,476

(22) Filed: Nov. 16, 2005

(30) Foreign Application Priority Data
Nov. 17, 2004 (EP) 2004EP-105839

(51) Int. Cl. G11C 7/06

(52) U.S. Cl. 365/189.07

(57) ABSTRACT

A ROM or flash memory with low power consumption includes control data used to retain information on the number of data bits that do not change relatively to an initial state. The proposed method allows the end of a reading operation to be determined with certainty, even under the effect of variable external factors. The memory's output amplifiers can be stopped as soon as they are not used in order to reduce consumption.

### CROSS REFERENCE TO RELATED APPLICATION

The present invention claims priority of European Patent Application EP04105839.7 filed on Nov. 17, 2004 in the European Patent Office, the disclosure of which is hereby incorporated by reference.

1. Technical Field

The present invention concerns a method for accessing a memory and the corresponding device and notably, but not exclusively, a method for reading a flash, ROM or DRAM memory for a microcontroller having low power consumption, as well as the microcontroller and the memory module implementing such a method.

2. Related Art

Modern electronic equipments rely always more on the use of solid-state numerical memories, for example RAM, DRAM, Flash or ROM memories, for storing information elements such as data or program instructions. Such memories are available in the form of electronic components or in the form of circuit modules integrated in more complex devices, for example in microcontrollers or in microprocessor systems.

During reading of a memory position, the data are transferred to the memory's reading register with a speed that is not the same for all the bits nor for all the devices. The contents of the reading register thus undergo a transitory period during which the contents are erroneous before stabilizing at the required value.

The speed of transfer can also depend on variable external factors, for example on the temperature and the power voltage.

In order to avoid reading errors, it is usual to introduce between the memory addressing and the register reading a fixed waiting time sufficiently long so that all the bits of the reading register stabilize. In order to accommodate the tolerances and the variations of the response time, this waiting time necessarily comprises a considerable security margin. It is obvious that this waiting time has negative consequences on the processing speed and on the power consumption.

The power consumption of memories, for example of flash-type memories, consists mainly in the consumption of the output amplifiers. These amplifiers must be fast so that the circuit can work quickly but are normally stopped after having read one memory word. In order to minimize the waiting time and the cyclical use ratio of the amplifiers, it has been proposed to use one or several parity bits for each memory word to generate a signal indicating that the memory has been successfully read. This method avoids unnecessarily long fixed waiting times but does not allow all errors to be excluded since the data and parity values can accidentally correspond during the transitory period.

Another inconvenience of this approach is that the circuit required for verifying the parity is complex and causes additional power consumption.

### DISCLOSURE OF THE INVENTION

One aim of the present invention is to propose a method for accessing a memory that is free of the limitations of the known methods. In particular, the present invention has the aim of proposing a method for accessing a memory allowing the waiting time to be reduced.

Another aim of the invention is to propose a memory circuit and a microcontroller that are faster and have lower power consumption that the prior art circuits and devices.

These aims are achieved by the method and by the devices that are the object of the independent claims of corresponding category, and notably by a method for accessing a memory, said memory comprising a storage area and output means for extracting information contained in said storage area, the method including the steps of:
loading each bit of said output means with an initial value;
transferring numeric data of said storage area to said output means;
obtaining control data expressing the number of bits of said numeric data that are identical to said initial value;
verifying whether said control data correspond to the number of bits of said numeric data in said output means having said initial value.

The above aims are also achieved by a memory device including:
a storage area for storing numeric information;
output means for extracting the numeric data contained in said storage area, said output means being loaded with an initial value before each reading operation;
a control device arranged so as to compare the number of bits of said numeric data in said output means having said initial value with a control code expressing the expected number of bits of said numeric data having said initial value.

The above aims are also achieved by a microcontroller including a memory device according to the invention.

### BRIEF DESCRIPTION OF THE DRAWINGS

The present invention will be better understood by reading the description given by way of example and illustrated by the attached figures in which:

FIG. 1 represents the structure of a memory organized in m words of n bits;

FIG. 2 represents a possible structure of one memory position comprising the control bits according to the invention;

The chronogram of FIG. 3 represents diagrammatically the evolution of the signals during access to the memory according to the inventive method.

### EMBODIMENT(S) OF THE INVENTION

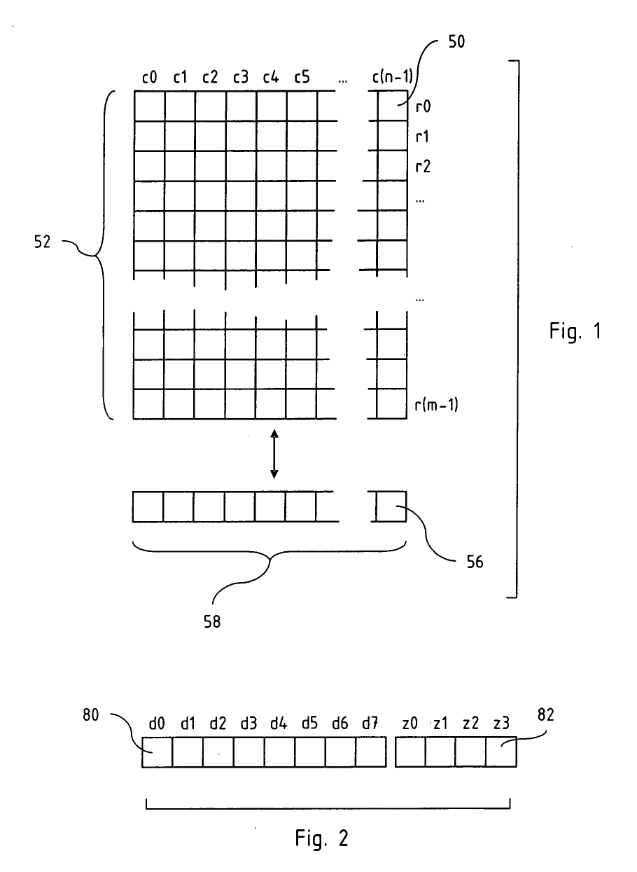

FIG. 1 illustrates a memory of known type, organized according to a matrix of m lines 52 and n columns 58. Each of the lines corresponds to a position of n bit memory. When a word is read from the memory, an address from 0 to m-1 is written into a register (not represented), for example, and the contents of the corresponding memory line is transferred to the output register 56. The memory will generally be part of a complex circuit (not represented), for example of a system with microcontroller.

This addressing method is presented by way of example only and the invention also includes several other methods and variant embodiments for addressing the contents of a ROM or RAM memory, which it would be too tedious to enumerate here.

At the beginning of the reading operation, the output register 56 is preloaded with the same binary value for all bits, for example all bits at zero or all bits at 1.

In a typical, though not exhaustive, case, the Inventive memory is a non-volatile flash memory or a programmable ROM memory, designed to store the program instructions for a system with microcontroller. The reading operations are thus much more frequent, for this type of memory, than the writing operations and their impact on the power consumption is predominant.

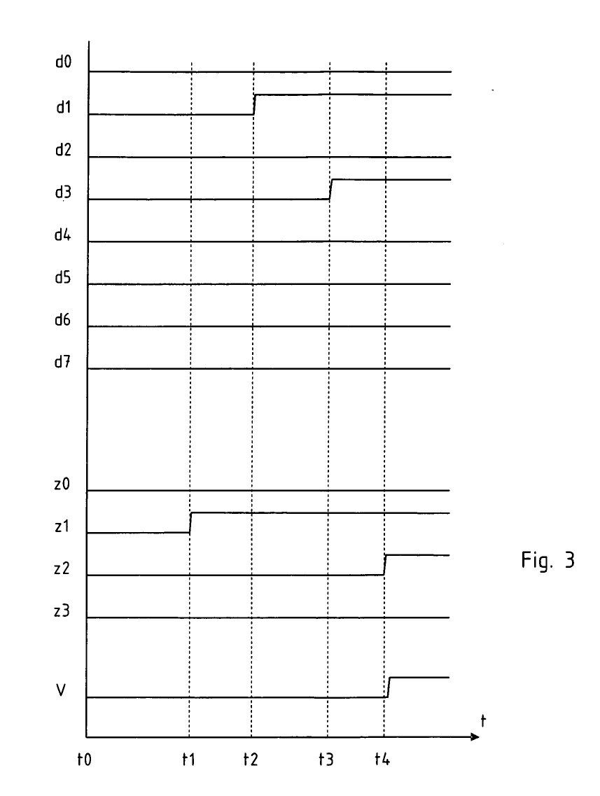

FIG. 2 represents a possible structure of a memory position according to the invention. A memory position includes a data field comprising a predetermined number of data bits d0-d7 and a control field comprising one or more control bits z0-z3. In this example, each word includes 8 data bits. It is however obvious that the present invention can be applied to a memory with any number whatsoever of data bits per word, for example 4, 16, 24, 22 or 36.

ROM or flash memories are usually read by loading (or unloading) their columns, or b y any other principle having the same characteristics. In the case of a memory read by loading, the output register bits are all in an initial zero state and switch to a desired state during reading. The loading is more or less fast on different columns but it is generally monotonous, in the sense that a “0” remains a “0” or becomes a “1” but a “1” never reverts to the “1” state. There is thus no—or practically no—glitch in the bits of the output register 56. (By analogy, in the case of a memory read by unloading, the initial value “1” of the bits of the output register 56 possibly switches to “0” after a certain more or less short lapse of time, but it does not revert to “1”).

According to one aspect of the invention, the number of bits that are to remain at zero is encoded in the memory, in the control field 82. If the word encoded in the data field is “01010000b”, one will have added in the control field 82 the code “0110b” which indicates that 6 bits must be at zero at the end of the reading.

When, in the output register 56, the number of bits at zero in the data field 80 corresponds to the value of the control field 82, all the bits of the register 56 have reached their final value and the memory Is ready. The memory preferably delivers a signal V indicating the correspondence between the number of bits at zero in the data field 80 and the value of the control field 82.

FIG. 3 represents a chronogram relative to the contents of the bits d0-d7 and z0-z3 of the output register during a reading operation of the memory according to the invention. The position of addressed memory contains for example the value “01010000b” in the data field 80 and the value “0110b” in the control field 82. At t=t0, all the bits d0-d7 and z0-z3 are at zero. There is thus no correspondence between the value of the data field 80, with 8 bits at zero, and the contents of the control register 82, which indicates 0 bits at zero. The value of the signal V is thus zero.

At the instant t=t1, the bit z1 passes to the high state. There is thus a “2” in the control field 82, but still 8 bits at zero in the data field 80. The signal V remains at zero.

At the instant t=t2, the bit d1 passes to high state. The is still no correspondence between the contents of the control field (2) and the number of bits at zero of the data field (7). The signal V remains at zero.

At the instant t=3, the bit d3 passes to high state. There is still no correspondence between the contents of the control field (2) and the number of bits at zero of the data field (6). The signal V remains at zero.

Finally, at t=t4, the bit z3 passes to high state. There is a correspondence between the contents of the control field (6) and the number of bits at zero of the data field (6). The signal V switches to “1” to signal that the memory is ready.

For a memory read by unloading, one will begin with “1” in all the bits of the register 56 and the number of bits that are to remain at “1” is encoded in the memory, in the control field 82.

The inventive technique has the advantage that the condition for acceptation Is never fulfilled as long as all the bits that must change value have not done it. The number of bits at “0” in the data field decreases monotonously whilst the contents of the control field 82 increases monotonously.

The technique obviously extends to any arbitrary number of bits, with the proviso that the control field must be sufficiently large to contain a binary number corresponding to the number of data bits of the data field 80. In the example illustrated in FIG. 2, 4 bits z0-z3 are necessary to express eight in binary. In the case of a 22-bit memory, a control code with 6 bits will be required.

The signal V indicating the end of a reading operation could be used for example to reduce the memory's power consumption, for example by stopping the output amplifiers or other components when their functions were not required.

Furthermore, the signal V can be used to detect malfunctions of the memory, for example if the memory is not ready before the next instruction from the CPU or before a predetermined maximum period of time.

The generating of the signal V according to the Invention can be effected by computing means inside the memory itself or by an external circuit.

The method of the present invention can also be implemented by software. In this case, a processor programmed to this effect checks the correspondence of the data and control fields.

If the memory device generates the signal V autonomously, it is not necessary for the control bits 82 to be accessible from outside the memory. It is also preferable, in this case, for the memory device to comprise autonomous means for generating the control bits 82 during a writing operation.

The example described here above comprises a memory organized so as to store, for each possible address, against each data word, the number of bits at zero (respectively at 1 in the case of a memory read by unloading). However, it would also be possible to make, in the frame of the present invention, devices in which the number of bits at zero is not stored but computed from the contents of the memory for each reading operation.

Detecting the memory access time is very important for systems whose clock frequency is programmable (this is the case for the majority of current microcontroller systems). The system can thus determine whether the clock frequency is too fast for the memory and compensate this “overspeed”, for example by adding waiting cycles or by adapting the clock rate, in order to continue executing valid instructions or reading correct data. An interruption could possibly be generated so that the software can apply appropriate measures for managing the situation, for example slowing down the clock, generating an exception, acting on the power voltage or any other appropriate measure.

One advantage of the present invention is that the microcontroller system provided with an access time control memory according to the invention can adapt autonomously to the memory's speed variations, for example to variations linked to fluctuations in temperature or power voltage, whilst always ensuring an optimum power consumption.

Finally, the same principle can also serve for controlling the memory writing, if the memory starts from the same state in writing as in reading.

In a variant embodiment of the present invention, the control field 82 is used for detecting memory errors. Data are accessed synchronously, in the sense that each reading operation is effected in a predetermined time and without awaiting an end-of-reading signal V.

According to this embodiment of the invention, after a predetermined lapse of time from starting a reading operation, one will check whether the number of bits that are not to change state, stored in the control field 82, corresponds to the number of bits that have not changed in the data field.

When there is a correspondence between the number of bits that have not changed value in the data field and the contents of the control field 82, the system concludes that the reading was performed correctly and moves on to executing the following function.

On the other hand, if the number of bits that have not change sign does not correspond to the control value 82, the system generates a signal to indicate a memory error, which can derive from a reading process that is too fast but also from an accidental alteration of the memory's contents. Following the error signal, the system can possibly apply appropriate measures to manage the situation, for example slow down the clock, generate an exception, act on the power voltage or any other appropriate measure.

1. Method for accessing a memory, said memory comprising a storage area (50) and output means for extracting information contained in said storage area (50), the method including the steps of:
loading each bit of said output means with an initial value;
transferring numeric data of said storage area (50) to said output means (58);
obtaining control data expressing the number of bits of said numeric data that are identical to said initial value;
verifying whether said control data correspond to the number of bits of said numeric data in said output means (58) having said initial value.

2. Method according to claim 1, wherein said output means include an output register (56) having a data field (80) and a control field (82) and wherein said numeric data are transferred from said storage area to said data field (80) and wherein said control data are transferred from said storage area to said control field (82).

3. Method according to claim 1, including a step of generating an end-of-reading signal when said control data correspond to the number of bits of said numeric data in said output means (58) having said initial value.

4. Method according to claim 1, said storage area being organized in addressable lines, each line being capable of containing a data word and said control code, said control data being read from the storage area.

5. Method according to claim 1, including a step of computing said control code.

6. Method according to claim 1, wherein the bit transitions of said output means are monotonous.

7. Method according to claim 1, wherein an error signal is generated when said control data do not correspond to the number of bits of said numeric data in said output means (58) having said initial value.

8. Memory device designed so as to apply the access method according to claim 1.

9. Memory device, including:
a storage area (50) for storing numeric information;
output means for extracting the numeric data contained in said storage area (50), said output means being loaded with an initial value before each reading operation;
a control device arranged so as to compare the number of bits of said numeric data in said output means (58) having said initial value with a control code expressing the expected number of bits of said numeric data having said initial value.

10. Device according to claim 9, wherein said storage area is organized in addressable lines, each line being capable of containing a data word and said control code.

11. Device according to claim 9, wherein said control code is computed for each reading operation.

12. Device according to claim 9, capable of generating an end-of-reading signal when said control code corresponds to the number of bits of said numeric data in said output means (58) having said initial value.

13. Device according to claim 9, wherein the bit transitions of said output means are monotonous.

14. Microcontroller including a device according to claim 9.

15. Microcontroller according to the preceding claim, designed so as to adapt to the reading speed of the memory device.
